(19) United States
(12) Patent Application Publication
(10) Pub. No.: US 2015/0129744 A1
(43) Pub. Date: May 14, 2015

(54) A/D CONVERTER, SOLID-STATE IMAGE SENSOR AND IMAGING SYSTEM

(71) Applicant: Canon Kabushiki Kaisha, Tokyo (JP)

(72) Inventors: Kazuhiro Sonoda, Kawasaki-shi (JP); Shintaro Takenaka, Yokohama-shi (JP)

(21) Appl. No.: 14/520,426

(22) Filed: Oct. 22, 2014

(30) Foreign Application Priority Data
Nov. 14, 2013 (JP) 2013-236262

(51) Int. Cl. H03M 1/34; H03K 3/037; H03K 3/64

(52) U.S. Cl. CPC H03M 1/34; H03K 3/64; H03K 3/037
USPC 250/206; 341/155

(57) ABSTRACT

An A/D converter includes a comparator configured to compare an input voltage and a reference signal changing monotonically with respect to time and output a comparison result signal indicating a comparison result, a pulse signal generation circuit configured to generate a pulse signal in accordance with the comparison result signal, a counting unit configured to receive a first clock signal, and to count the first clock signal from a start of changing a level of the reference signal to when a level of the comparison result signal is changed, and a latch unit configured to latch the pulse signal at a timing which is defined by a plurality of clock signals including a second clock signal in phase with the first clock signal and a third clock signal having a different phase from that of the second clock signal.

### BACKGROUND OF THE INVENTION

1. Field of the Invention

The present invention relates to an A/D converter (analog/digital converter), a solid-state image sensor, and an imaging system.

2. Description of the Related Art

As a technique for increasing the resolution of an A/D converter mounted in a solid-state image sensor, an A/D converter using clock signals having different phases implements a high resolution without increasing the frequency of the clock signal.

An A/D converter disclosed in Japanese Patent Laid-Open No. 2010-258817 is of a type which compares an input voltage and a reference voltage of a ramp waveform by a comparator, and obtains the upper bit by counting a clock signal by a counter, that is, a time until the output from the comparator is inverted. The A/D converter is configured to obtain data lower than a value counted by the counter using a plurality of clock signals whose phases shift by 45°. In Japanese Patent Laid-Open No. 2010-258817, however, a resolution corresponding to the phase difference of the clock signal can only be obtained.

### SUMMARY OF THE INVENTION

According to one aspect of the present invention, there is provided an A/D converter comprising a comparator configured to compare an input voltage and a reference signal changing monotonically with respect to time, and output a comparison result signal indicating a comparison result, a pulse signal generation circuit configured to generate a pulse signal in accordance with the comparison result signal, a counting unit configured to receive a first clock signal, and to count the first clock signal from a start of changing a level of the reference signal to when a level of the comparison result signal is changed and a latch unit configured to latch the pulse signal at a timing which is defined by a plurality of clock signals including a second clock signal in phase with the first clock signal and a third clock signal having a different phase from that of the second clock signal.

Further features of the present invention will become apparent from the following description of exemplary embodiments with reference to the attached drawings.

### BRIEF DESCRIPTION OF THE DRAWINGS

FIG. 1 is a diagram showing an example of the arrangement of an A/D converter according to the first embodiment of the present invention;

FIG. 2 is a timing chart showing the operation of the A/D converter according to the first embodiment of the present invention;

FIG. 3 is a diagram showing an example of the arrangement of a differentiating circuit of the A/D converter according to the first embodiment of the present invention;

FIG. 4 is a diagram showing an example of the arrangement of a latch unit of the A/D converter according to the first embodiment of the present invention;

FIG. 5 is a diagram showing an example of the arrangement of a clock signal gate circuit of the A/D converter according to the first embodiment of the present invention;

FIG. 6 is a diagram showing an example of the arrangement of a counting unit of the A/D converter according to the first embodiment of the present invention;

FIGS. 7A to 7C show timing charts each showing the operation of the A/D converter according to the first embodiment of the present invention;

FIG. 8 is a table showing lower count values (decimal numbers) which correspond to lower extension codes (binary numbers) of the A/D converter according to the first embodiment of the present invention;

FIGS. 9A and 9B show timing charts each showing the operation of the A/D converter according to the first embodiment of the present invention;

FIGS. 10A and 10B show timing charts each showing the operation of the A/D converter according to the first embodiment of the present invention;

FIG. 11 is a diagram showing an example of the arrangement of a solid-state image capturing apparatus including the A/D converter according to the first embodiment of the present invention;

FIG. 12 is a diagram showing an example of the arrangement of an A/D converter according to the second embodiment of the present invention; and

FIG. 13 is a diagram showing an example of the arrangement of an imaging system according to the third embodiment of the present invention.

### DESCRIPTION OF THE EMBODIMENTS

### First Embodiment

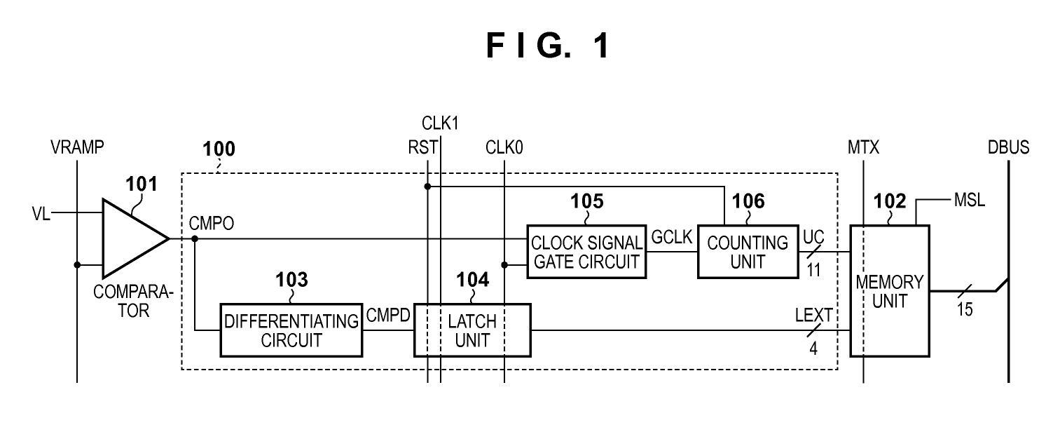

FIG. 1 shows an example of the arrangement of an A/D converter according to the present invention. The A/D converter according to this embodiment includes a digital code generation unit 100, a comparator 101, and a memory unit 102. The digital code generation unit 100 includes a differentiating circuit 103, a latch unit 104, a clock signal gate circuit 105, and a counting unit 106. The comparator 101 compares an input voltage VL with a ramp signal VRAMP of a ramp waveform whose voltage value changes linearly with time, and outputs a comparison result signal CMPO in accordance with the result to the differentiating circuit 103 and the clock signal gate circuit 105. The clock signal gate circuit 105 outputs, to the counting unit 106, a gated clock signal GCLK which is obtained by gating a clock signal CLK0 at an inversion timing of the comparison result signal CMPO from the comparator 101. In this embodiment, the gated clock signal GCLK is the first clock signal.

The counting unit 106 performs a count-up operation each time the logic level of the gated clock signal GCLK transits from Low to High, and outputs, to the memory unit 102, a count value as an upper count value UC representing the upper digit value of digital data output of A/D conversion. The differentiating circuit 103 is a pulse generation circuit which generates a pulse signal CMPD by differentiating the comparison result signal CMPO from the comparator 101. The latch unit 104 receives the pulse signal CMPD. The latch unit 104 also receives two clock signals CLK0 and CLK1 whose phases are different from each other by π/2. The latch unit 104 further receives both a clock signal CLK0_B and a clock signal CLK1_B which are formed by the leading edges and the trailing edges of the clock signals CLK0 and CLK1, and shifted by π/2 in their phases. In this embodiment, the clock signals CLK0 and CLK1 are the second clock signal and the third clock signal, respectively. The latch unit 104 latches the pulse signal CMPD at a rising timing of four clock signals having different phases. A latched signal is output to the memory unit 102 as a lower extension code LEXT which represents lower digit digital data concatenating to the upper count value UC.

The memory unit 102 holds the upper count value UC output from the counting unit 106 and the lower extension code LEXT output from the latch unit 104. When the memory unit 102 is selected by a memory selection signal MSL, a held memory value is read out to a data bus DBUS. The lower extension code LEXT cannot be concatenated with the upper count value UC because it is not the same binary code as that of the counting unit as it is. In this embodiment, the upper count value UC and a lower count value LC are concatenated with each other after the lower extension code LEXT is decoded and corrected to the lower count value LC by a signal processing circuit (not shown) connected to the data bus DBUS.

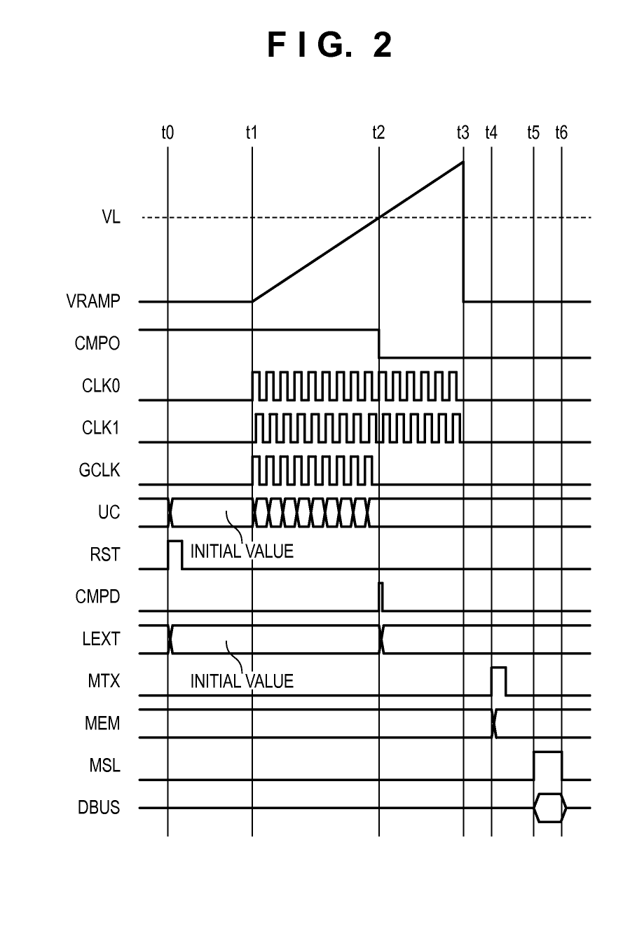

An overview of the operation of the A/D converter will now be described with reference to a timing chart shown in FIG. 2.

When the logic level of a reset signal RST transits from Low to High at a time t0, the counting unit 106 and the latch unit 104 are reset to initial values.

From a time t1 to a time t3, the comparator 101 compares an input voltage VL and the ramp signal VRAMP whose signal level changes monotonically over time. At the time t1, the signal level of the ramp signal VRAMP starts to rise. Simultaneously, two clock signals CLK0 and CLK1 whose phases are different from each other by π/2 start to output. The counting unit 106 receives the gated clock signal GCLK obtained by gating the clock signal CLK0 with the comparison result signal CMPO. The counting unit 106 is counted up by the gated clock signal GCLK. The gated clock signal GCLK is in phase with the clock signal CLK0.

At a time t2, when the ramp signal VRAMP exceeds the input voltage VL, the logic level of the comparison result signal CMPO output from the comparator 101 transits from High to Low. The clock signal gate circuit 105 generates the gated clock signal GCLK by gating the clock signal CLK0 with the comparison result signal CMPO. The gated clock signal GCLK stops a periodic signal change as the logic level of the comparison result signal CMPO transits from High to Low. At that time, the counting unit 106 holds the upper count value UC. On the other hand, the pulse signal CMPD is output from the differentiating circuit 103 in accordance with the comparison result signal CMPO. The latch unit 104 latches the pulse signal CMPD by four different clock signals in total having inverted signals of the clock signals CLK0 and CLK1, and the clock signals CLK0 and CLK1, respectively. A value latched by the latch unit 104 is held by the latch unit 104 as the lower extension code LEXT until the logic level of the reset signal RST becomes High next.

The upper count value UC is a value corresponding to a digital code which counts a period from the time t1 when comparison between the ramp signal VRAMP and the input voltage VL starts to a time when the ramp signal VRAMP exceeds the input voltage VL. The lower extension code LEXT is obtained by latching the value of the pulse signal CMPD by a plurality of clock signals whose phase difference is smaller than one cycle (2π) of the clock signal. Hence, the lower extension code LEXT represents a digital code in a unit smaller than 1 LSB of the upper count value.

The logic level of a memory transfer signal MTX transits from Low to High at a time t4, the upper count value UC and the lower extension code LEXT are written from the counting unit 106 and the latch unit 104 to the memory unit 102, and held. In a period from a time t5 to a time t6 when the logic level of the memory selection signal MSL becomes High, a data holding value MEM held in the memory unit 102 is output to the data bus DBUS. After transferring the upper count value UC and the lower extension code LEXT to the memory unit 102, the counting unit 106 and the latch unit 104 may start a next A/D conversion operation before finishing outputting the data holding value MEM from the memory unit 102. That is, at least a part of the A/D conversion operation and horizontal scanning which outputs the data holding value MEM from the memory unit 102 may be performed in parallel.

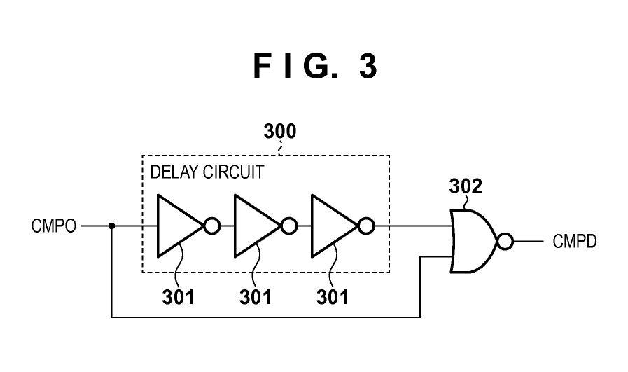

Next, the circuit arrangement of the digital code generation unit 100 will be described with reference to FIG. 3. FIG. 3 is a circuit diagram showing an example of the differentiating circuit 103 which functions as a pulse signal generation circuit in the digital code generation unit 100. The comparison result signal CMPO input to the differentiating circuit 103 is connected to the input of a delay circuit 300 and one input of a NOR gate 302. The output of the delay circuit 300 is connected to the other input of the NOR gate 302. In this embodiment, the delay circuit 300 includes three NOT gates 301, and detects the trailing edge of the comparison result signal CMPO. The logic level of the pulse signal CMPD becomes High at the same time as the falling of the comparison result signal CMPO, and returns to Low level with a delay by a delay time generated in the delay circuit 300. Therefore, the delay time generated in the delay circuit 300 is adjusted to adjust the pulse width of the pulse signal CMPD. In order to adjust the delay time, for example, the number of stages of the NOT gates included in the delay circuit 300 or the delay amount of each NOT gate is changed. The pulse signal CMPD is output to the latch unit 104.

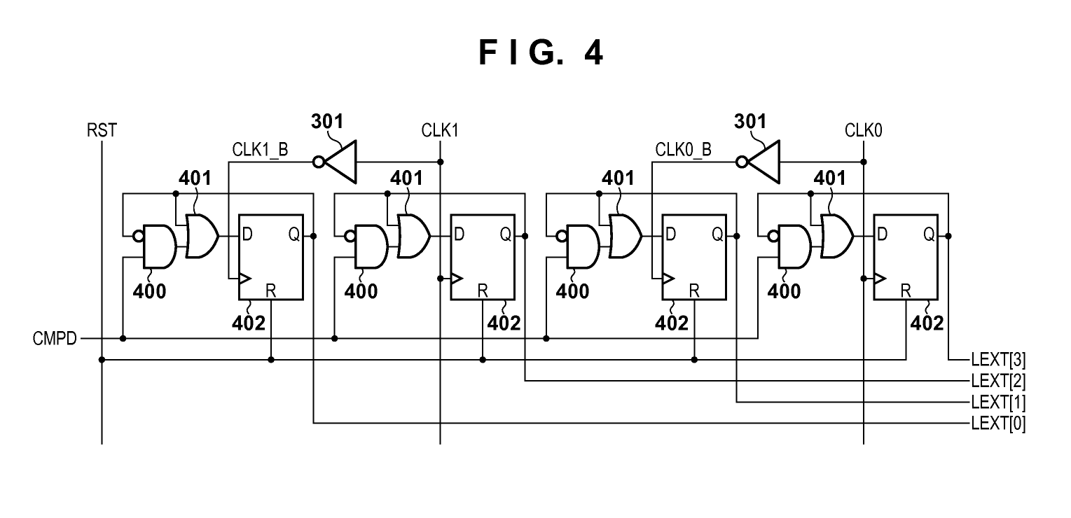

FIG. 4 shows an example of a circuit of the latch unit 104 included in the digital code generation unit 100. First, a description will be made by focusing on a latch (D flip-flops 402) outputting an uppermost lower extension code (LEXT [3]). One input of a AND gate 400 receives the pulse signal CMPD input from the differentiating circuit 103 to the latch unit 104. The other input of the AND gate 400 serves as an inverting input, and the Q output of the D flip-flop 402 is connected to it. The output of the AND gate 400 is connected to a corresponding one of the inputs of the OR gates 401. The Q output of the D flip-flop 402 is connected to the other input of a corresponding one of the OR gates 401. The output of the OR gate 401 is connected to a corresponding one of the D inputs of the D flip-flops 402. The reset input of the D flip-flop 402 receives the reset signal RST input to the latch unit 104. The clock signal input of the D flip-flop 402 receives the clock signal CLK0 input to the latch unit 104.

The logic level of the Q output of the D flip-flop 402 is initialized to Low when the logic level of the reset signal RST is High. When the logic level of the Q output is Low, the other input of the AND gate 400 is High because it is an inverting input. This makes it possible to read and latch the value of the pulse signal CMPD at the leading edge of the clock signal CLK0. On the other hand, when the logic level of the Q output is High, it holds High irrespective of the logic level of the pulse signal CMPD because the other input of the OR gate 401 is High. That is, once the latch unit 104 reads and latches a state in which the logic level of the pulse signal CMPD is High, the logic level of the LEXT [3] holds High unless otherwise initialized by the reset signal RST. As for lower extension codes LEXT [0], LEXT [1], and LEXT [2], the phases of the clock signals to read are mutually different between the clock signals. The lower extension code LEXT [0] is obtained by latching the value of the pulse signal CMPD at a timing of the leading edge of a clock signal CLK1_B serving as an inverted clock signal of the clock signal CLK1. The lower extension code LEXT [1] is obtained by latching the value of the pulse signal CMPD at a timing of the leading edge of a clock signal CLK0_B serving as an inverted clock signal of the clock signal CLK0. The lower extension code LEXT [2] is obtained by latching the value of the pulse signal CMPD at a timing of the leading edge of the clock signal CLK1. As described above, four clock signals (CLK0, CLK1, CLK0_B, and CLK1_B) having the different phases are used to read the value of the pulse signal CMPD. The latch unit 104 latches the logic level of the pulse signal CMPD at respective timings of the leading edges of four clock signals having the different phases. The latch unit 104 has a function of holding the logic state unless otherwise initialized by the reset signal RST.

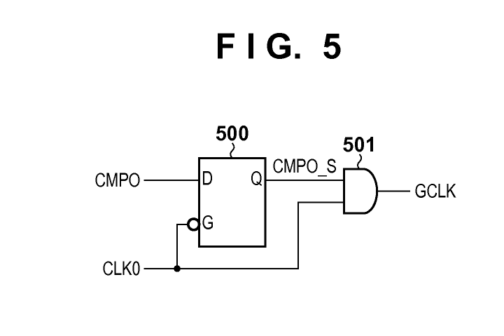

FIG. 5 shows an example of the clock signal gate circuit 105 included in the digital code generation unit 100. The comparison result signal CMPO input from the comparator 101 to the clock signal gate circuit 105 is connected to the D input of a D latch 500 which functions as a latch circuit. The gate input of the D latch 500 serves as an inverting input, and receives the clock signal CLK0. The Q output of the D latch 500 is connected to an AND gate 501. The clock signal CLK0 is connected to the other input of the AND gate 501.

A latch output signal CMPO_S serving as the Q output of the D latch 500 corresponds to the comparison result signal CMPO when the logic level of the clock signal CLK0 is Low, and becomes a signal which is obtained by gating the comparison result signal CMPO (holds an immediately preceding value of CMPO) when the logic level of the clock signal CLK0 is High. The AND gate 501 causes the clock signal CLK0 to pass when the logic level of the latch output signal CMPO_S is High, and inhibits outputting the clock signal CLK0 when the logic level of the latch output signal CMPO_S is Low. A period during which the logic level of the gated clock signal GCLK is High by the behavior of the D latch 500 is held, independently of an inverting timing of the comparison result signal CMPO, only during a given period when the clock signal CLK0 is High. That is, the gated clock signal GCLK does not include a short pulse which causes the malfunction of the counting unit 106 on a subsequent stage.

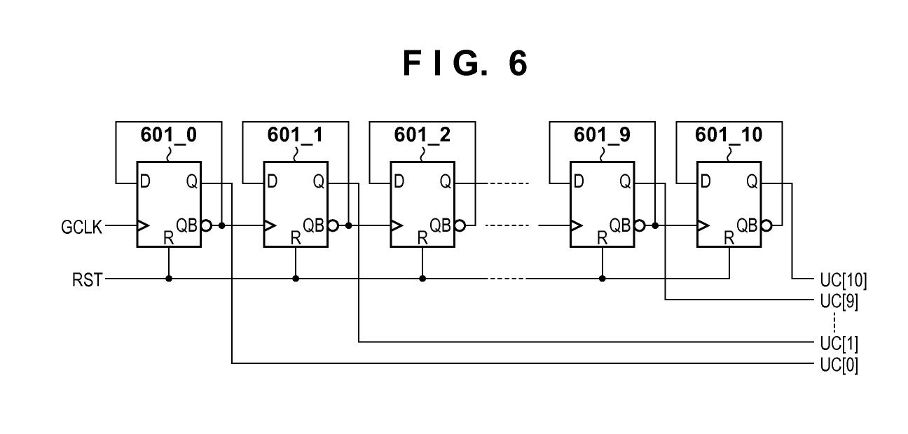

FIG. 6 shows an example of the circuit of the counting unit 106 included in the digital code generation unit 100. The gated clock signal GCLK input to the counting unit 106 is connected to the clock signal input of a D flip-flop 601_0. Since the QB output of the D flip-flop 601_0 is connected to the D input of the D flip-flop 601_0 itself, it is a signal obtained by dividing the frequency of the GCLK into ½. The QB output of the D flip-flop 601_0 is connected to the clock signal input of a D flip-flop 601_1 on a next stage. A binary counter is formed by repeating this arrangement by a bit width required to perform counting. FIG. 6 shows a 11-bit binary counter in which 11-stage D flip-flops are connected. An upper count value UC [10:0] serving as the output of the binary counter is initialized to 0 upon receiving the reset signal RST. The binary counter is configured to start counting upon receiving the GCLK, and perform a count-up operation.

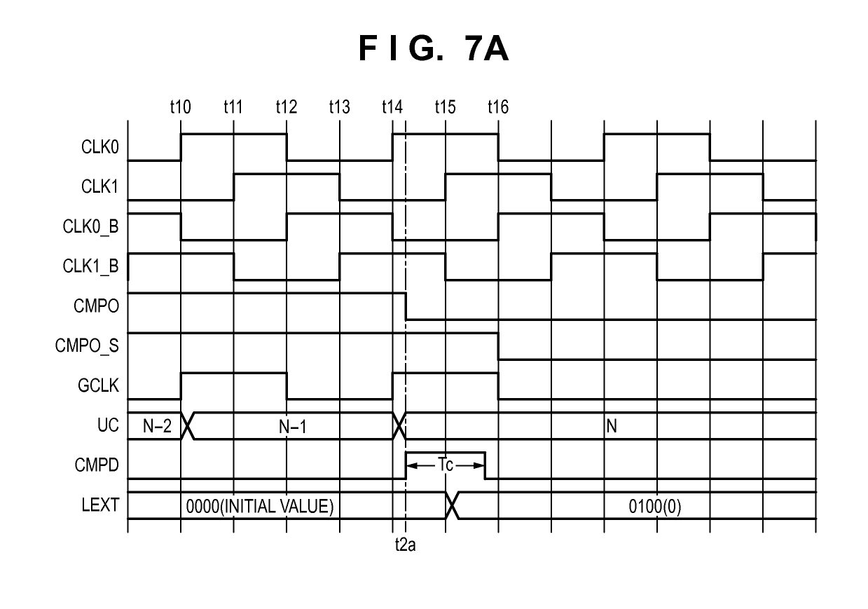

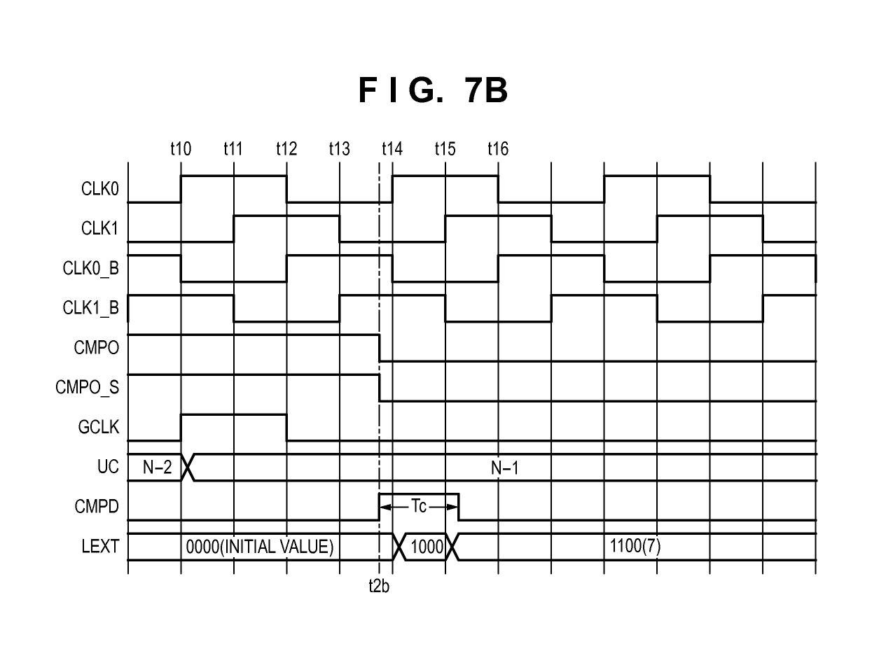

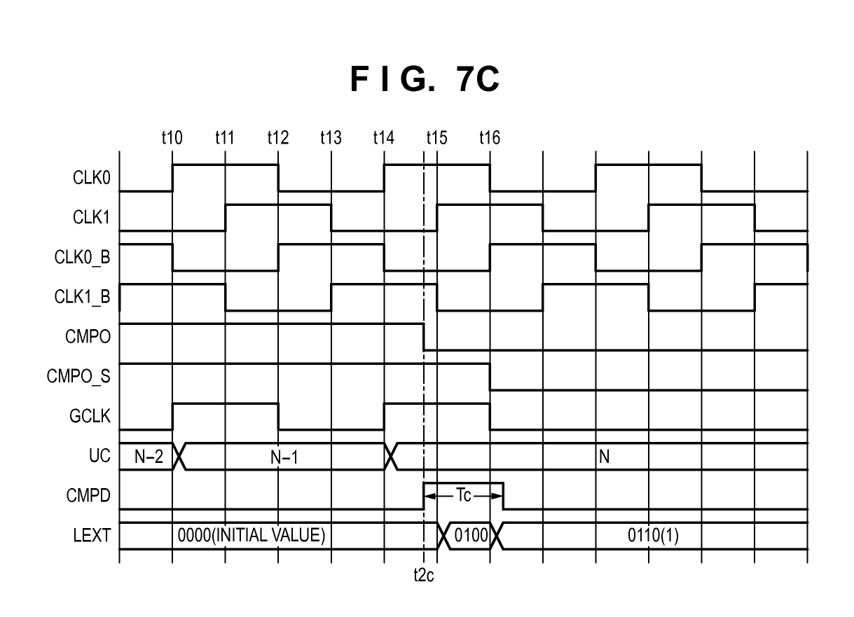

Next, the operation of the digital code generation unit 100 will be described in detail with reference to timing charts. FIGS. 7A, 7B and 7C are the detailed timing charts which magnify a portion in the vicinity of the time t2 (a timing when the output of the comparator 101 is inverted) shown in FIG. 2. FIGS. 7A, 7B and 7C show a relationship between the upper count value UC serving as the output of the counting unit 106 and the lower extension code LEXT serving as the output of the latch unit 104 when the inverting timing of the comparison result signal CMPO from the comparator changes with respect to the phase of the clock signal CLK0.

FIG. 7A is the timing chart when the comparison result signal CMPO is inverted at a time t2a slightly after the leading edge of the clock signal CLK0. At the time t2a, since the logic level of the clock signal CLK0 is High, the latch output signal CMPO_S holds the immediately preceding logic level until a time t16. Since the gated clock signal GCLK is AND of the latch output signal CMPO_S and the clock signal CLK0, it is equal to the clock signal CLK0 until the time t16. Accordingly, the count-up operation of the counting unit 106 is performed until a time t14. The upper count value UC is counted up to N−1 at a time t10 and N at the time t14, and holds N from then on. The pulse signal CMPD is a signal obtained by differentiating the falling of the comparison result signal CMPO. In this embodiment, a pulse width Tc of the pulse signal CMPD is adjusted to be larger than the phase difference π/2 between the clock signal CLK0 and the clock signal CLK1, and smaller than π. This adjustment of the pulse width is done by adjusting the delay time of the delay circuit 300 shown in FIG. 3.

The lower extension code LEXT is a value obtained when the value of the pulse signal CMPD is latched at rising timings (leading edge) of the clock signals CLK0, CLK1, CLK0_B, and CLK1_B. As shown in FIG. 4, the lower extension code LEXT [3] becomes a value obtained by latching the pulse signal CMPD with the rising of the clock signal CLK0. The respective lower extension codes LEXT [2], LEXT [1], and LEXT [0] correspond to values obtained by latching the pulse signal CMPD at the rising timings of the respective clock signals CLK1, CLK0_B, and CLK1_B. As for a timing shown in FIG. 7A, the High level of the pulse signal CMPD can only be latched at the rising timing of the clock signal CLK1 at a time t15. At this time, 0100 is held as a lower extension code LEXT [3:0].

FIG. 7B is the timing chart when the comparison result signal CMPO is inverted at a time t2b slightly before the leading edge of the clock signal CLK0. At the time t2b, since the logic level of the clock signal CLK0 is Low, the latch output CMPO_S becomes the comparison result signal CMPO. Since the gated clock signal GCLK is AND of the latch output signal CMPO_S and the clock signal CLK0, it is equal to the clock signal CLK0 until the time t2b. Accordingly, the count-up operation of the counting unit 106 is performed until the time t10. The upper count value UC is counted up to N−1 at the time t10, and holds N−1 from then on. In an example shown in FIG. 7B, the clock signal CLK0 which latches the pulse signal CMPD at the time t14 and the clock signal CLK1 which latches the pulse signal CMPD at the time t15. The clock signal CLK0 and the clock signal CLK1 read and latch the High level of the pulse signal CMPD. The clock signal CLK0_B and the clock signal CLK1_B do not latch the High level of the pulse signal CMPD. As a result, 1100 is held as the lower extension code LEXT [3:0].

FIG. 7C is the timing chart when the comparison result signal CMPO is inverted at a time t2c after the leading edge of the clock signal CLK0. The time t2c is a time which is a little later than the time t2a shown in FIG. 7A. At the time t2c, since the logic level of the comparison result signal CMPO is High, the latch output signal CMPO_S holds the immediately preceding logic level until the time t16. Since the gated clock signal GCLK is AND of the latch output signal CMPO_S and the clock signal CLK0, it is equal to the clock signal CLK0 until the time t16. Accordingly, the count-up operation of the counting unit 106 is performed until a time t14. The upper count value UC is counted up to N−1 at a time t10 and N at the time t14, and holds N from then on.

In an example shown in FIG. 7C, only the clock signal CLK1 whose leading edge is at the time t15 and the clock signal CLK0_B whose leading edge is at the time t16 can latch the High level of the pulse signal CMPD. That is, 0110 is held as the lower extension code LEXT [3:0].

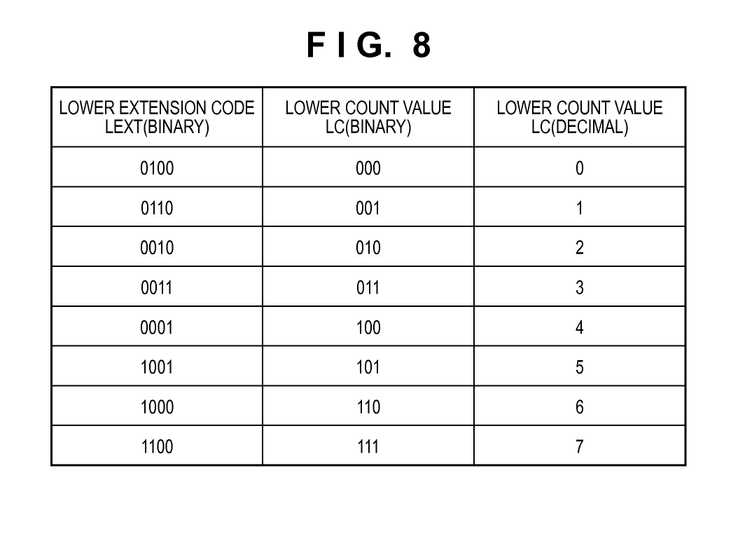

Since the value of the lower extension code LEXT shown in FIG. 7A to FIG. 7C is determined by a rule which is different from that of the upper count value UC, it cannot be directly concatenated with the lower position of the upper count value UC. FIG. 8 shows a decode table in which the 4-bit lower extension codes LEXT [3:0] are converted into a 3-bit lower count values LC [2:0]. In this embodiment, mutually different codes of codes having 1 by 1 bit and codes having 1 by 2 bits are arranged alternately in the lower extension code LEXT shown in FIG. 8. There are no codes having only 0 (no 1). This code sequence is achieved by adjusting the pulse width Tc of the pulse signal CMPD to be larger than π/2 which is the minimum value of a phase difference between the mutual clock signals, and smaller than π. For example, when the pulse width Tc of the pulse signal CMPD is smaller than the phase difference between the CLK0 and the CLK1, a timing at which no clock signals latch the High level of the pulse signal CMPD occurs in the lower extension code. In this case, depending on a timing at which the comparison result signal CMPO is inverted, a plurality of codes having no 1 for even 1 bit are generated. This makes it impossible to confirm a position and decode the codes. When the pulse width of the pulse signal CMPD is π or larger, 1 is set for 3 bits. Furthermore, when the pulse width of the pulse signal CMPD is 3π/2 or more, that is, three times as large as the minimum value of the mutual clock signals, a plurality of timings which include the rising of four clock signals are generated. In this case as well, a plurality of cases in which all bits are 1 occur. This makes it impossible to confirm a lower digit position. In this embodiment, a position in ⅛ cycle within one clock signal, at which inversion of the comparison result signal CMPO has occurred, is detected by latching the pulse signal CMPD having a predetermined pulse width by four clock signals whose phases shift by π/2. Therefore, in a case in which four clock signals having the phase difference by π/2 are used as in this embodiment, the pulse signal CMPD can accurately detect the phase position of the comparison result signal with respect to the clock signals when its pulse width corresponds to 3π/4 of a clock signal cycle.

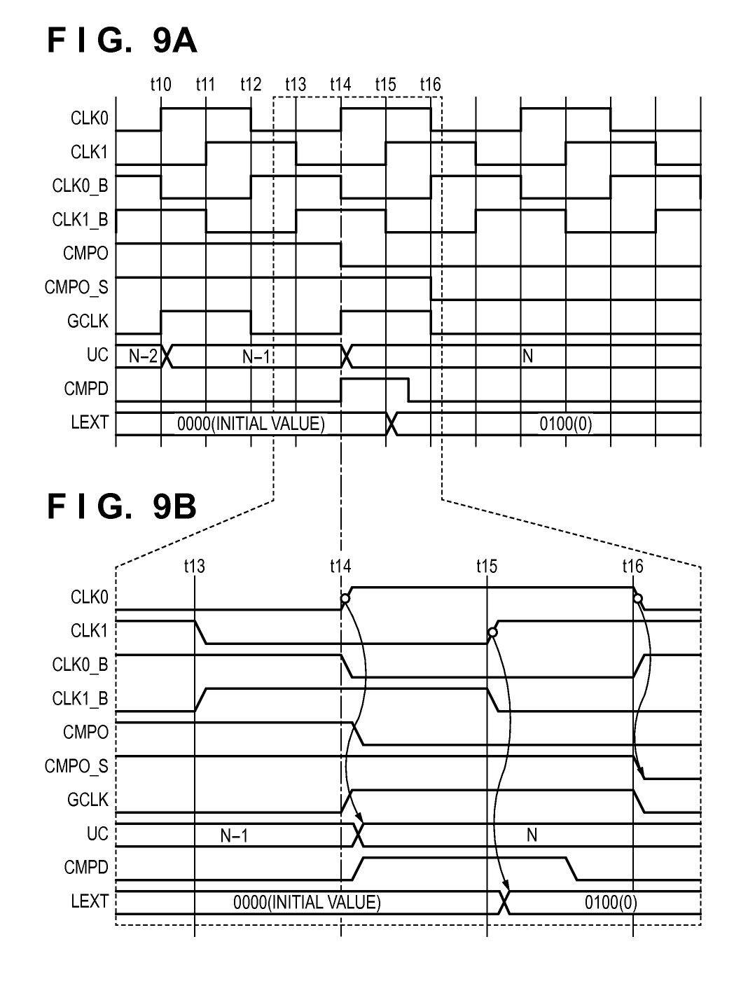

Next, a detailed description will be made on a relationship between the upper count value UC and the lower extension code LEXT in the case of inversion of the comparison result signal CMPO in the vicinity of the leading edge of the clock signal CLK0 which is a count-up timing of the upper count value UC. FIG. 9A and FIG. 9B show timing charts when the comparison result signal CMPO is inverted slightly after the leading edge of the clock signal CLK0. FIG. 9B shows the timing chart which magnifies a time t13 to the time t16 out of a period shown in FIG. 9A. At the time t14, two operations, namely, latching of the comparison result signal CMPO by the D latch 500 and count-up of the upper count value UC by the counting unit 106 are performed in synchronism with the rising of the clock signal CLK0. Since the comparison result signal CMPO is inverted slightly after the leading edge of the clock signal CLK0, the logic level of the latch output signal CMPO_S is held High until the time t16 in synchronism with the clock signal CLK0. Hence, because the gated clock signal GCLK is High until the time t16, the upper count value UC is counted up to N at the time t14. On the other hand, since the logic level of the pulse signal CMPD is Low at the time t14, the lower extension code LEXT [3] holds Low at the time t14 when the clock signal CLK0 rises. At the following time t15 when the clock signal CLK1 rises, since the logic level of the pulse signal CMPD is High, the lower extension code LEXT [2] holds High. As a result, the upper count value UC becomes N, and the lower extension code LEXT becomes 0100 (000 if converted into the lower count value in the decode table of FIG. 8).

If the pulse signal CMPD is latched by the clock signal CLK0, the lower extension code becomes 1100 (111 if converted into the lower count value in the decode table of FIG. 8). Since the upper count value is N at this time, data of the upper count value UC and the lower extension code LEXT make errors. Such malfunction occurs when the count-up timing of the upper count value UC and a latch timing of the lower extension code LEXT are asynchronous to each other. According to the present invention, however, since two operations, namely, latching of the comparison result signal CMPO and the count-up of the upper count value UC by the counting unit 106 are performed in synchronism with the rising of the clock signal CLK0, the malfunction does not occur.

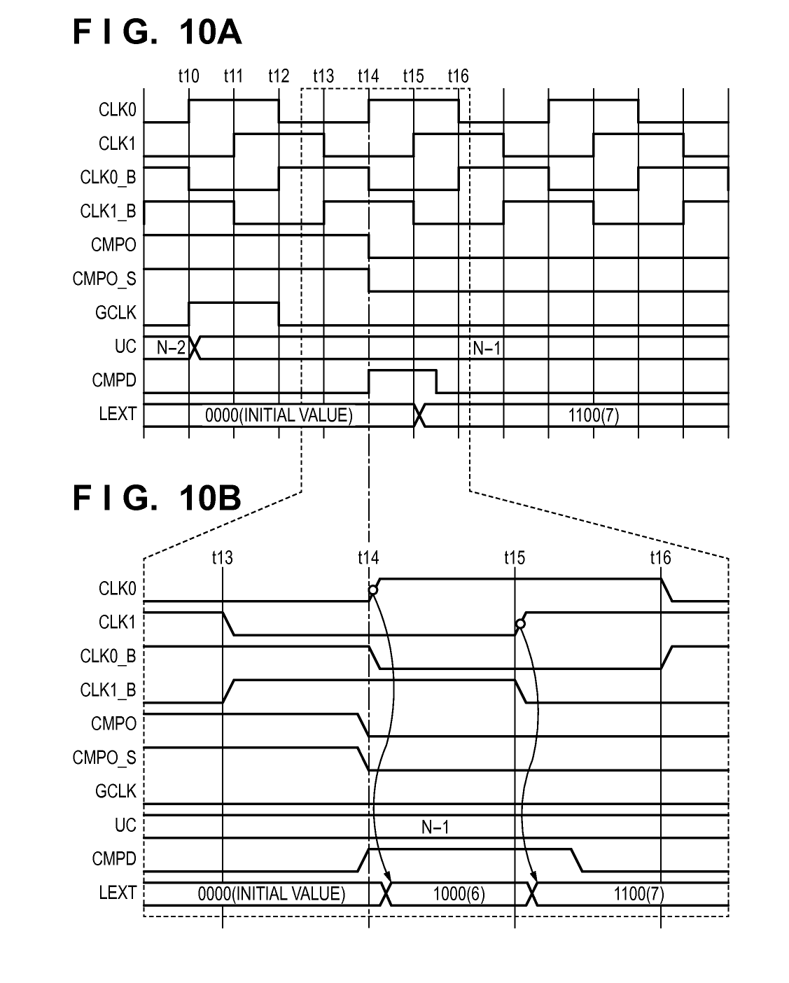

Operations will now be described with reference to FIG. 10A and FIG. 10B. FIG. 10A and FIG. 10B show timing charts when the comparison result signal CMPO is inverted slightly before the leading edge of the clock signal CLK0. FIG. 10B shows the timing chart which magnifies the time t13 to the time t16 out of a period shown in FIG. 10A. At the time t14, two operations, namely, the latching of the comparison result signal CMPO and the count-up of the upper count value UC are performed in synchronism with the rising of the clock signal CLK0. Since the comparison result signal CMPO is inverted slightly before the leading edge of the clock signal CLK0, the logic level of the latch output signal CMPO_S is inverted in the same way as the latch output signal CMPO slightly before the time t14. Hence, because the gated clock signal GCLK only outputs High until the time t12, the upper count value UC is not counted up to N at the time t14 and holds N−1. On the other hand, since the logic level of the pulse signal CMPD is High at the time t14, the lower extension code LEXT [3] holds High at the time t14. At the following time t15, since the logic level of the pulse signal CMPD is High, the lower extension code LEXT [2] holds High. As a result, the upper count value UC becomes N−1, and the lower extension code LEXT becomes 1100 (111 (BINARY), if converted into the lower count value in the decode table of FIG. 8). If the pulse signal CMPD is not latched by the clock signal CLK0, and the lower extension code is 0100 (000 (BINARY), if converted into the lower count value in the decode table of FIG. 8), the upper count value UC and the lower extension code LEXT make errors. This malfunction occurs when the count-up timing of the upper count value UC and the latch timing of the lower extension code LEXT are asynchronous to each other. According to the present invention, however, since two operations, namely, the latching of the comparison result signal CMPO and the count-up of the upper count value UC are performed in synchronism with the rising of the clock signal CLK0, the malfunction does not occur.

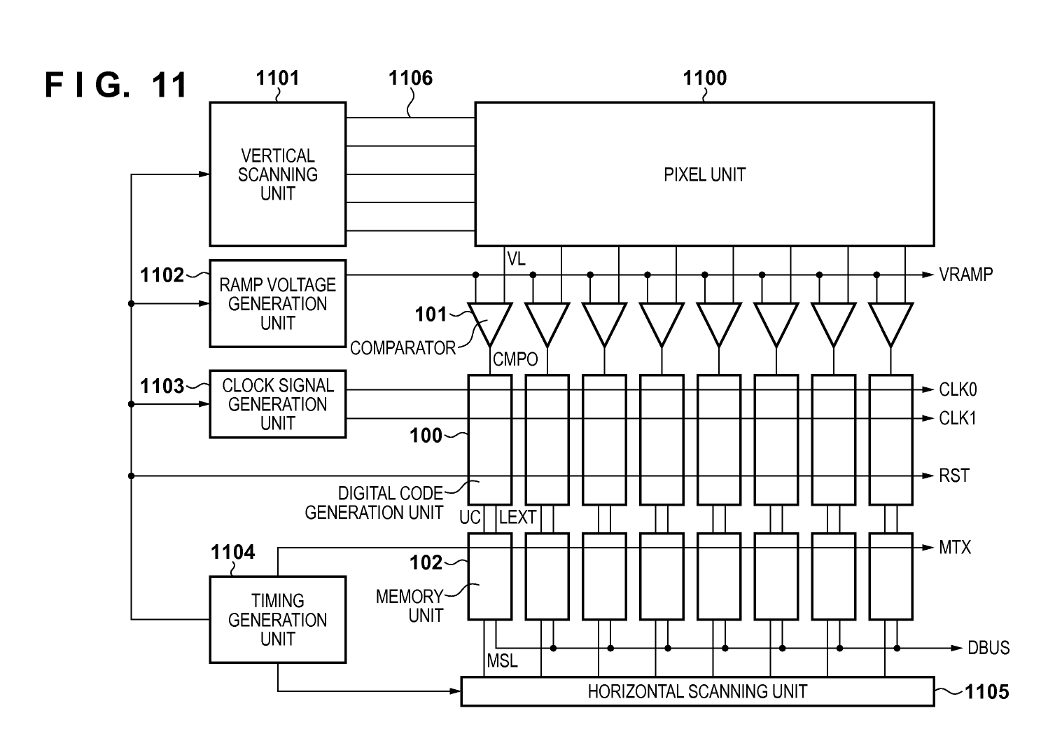

FIG. 11 is a block diagram showing a solid-state image sensor which uses the above-described A/D converter. In a pixel unit 1100, pixels (not shown) each including a photoelectric conversion unit which converts light entering a solid-state image capturing apparatus into an electric signal are two-dimensionally arranged in row and column directions. The A/D converter is arranged by column of the pixel unit 1100 where the pixels are arranged in a matrix. A vertical scanning unit 1101 selects the row of the pixel unit 1100 and reads out the electric signal from each photoelectric conversion unit on the row basis by outputting vertical selection signals 1106 and scanning the pixel unit sequentially. Each signal read out at this time is referred to as a pixel signal VL. Each comparator 101 of the A/D converter provided by the column receives the pixel signal VL read out on the row basis. The ramp signal VRAMP generated by a ramp voltage generation unit 1102 is a reference voltage to be compared with each pixel signal VL. Each comparator 101 receives the ramp signal VRAMP. Each comparator 101 compares the pixel signal VL with the ramp signal VRAMP, and outputs, as the comparison result signal, the signal CMPO of the logic level in accordance with the result to the digital code generation unit 100. Two clock signals CLK0 and CLK1 whose phases are different from each other by π/2 are input from a clock signal generation unit 1103 to the digital code generation units 100. The reset signal RST is also input from a timing generation unit 1104 to the digital code generation units 100. The operation performed inside each digital code generation unit 100 is omitted because it has already been described. Each digital code generation unit 100 outputs, to the memory unit 102, the upper count value UC and the lower extension code LEXT serving as a digital code corresponding to the pixel signal VL. Each memory unit 102 holds the upper count value UC and the lower extension code LEXT by the memory transfer signal MTX output from the timing generation unit 1104. A horizontal scanning unit 1105 reads out the upper count value UC and the lower extension code LEXT held by each memory unit 102 to the data bus DBUS by sequentially scanning the horizontal selection signal MSL. In FIG. 11, each lower extension code LEXT is decoded to generate the lower count value LC, and the upper count value UC and the lower count value LC are concatenated with each other in the signal processing circuit (not shown) connected to the data bus DBUS.

As described above, according to this embodiment, a mismatch does not occur in a relationship between timings of obtaining the upper count value UC and the lower count value LC. Furthermore, since only two clock signals having different phases are needed to obtain 3-bit lower counts, power consumption can be reduced by decreasing the number of clock signal lines and buffers. Moreover, since a phase difference between clock signals having different phases can be increased to π/2, it makes easy to increase a clock signal frequency while holding the phase difference. As a result, high resolution of the A/D converter can be achieved easily. A case in which the A/D converter according to this embodiment is applied to an APSC-size image sensor will also be exemplified. The width of the APSC-size image sensor is about 23 mm. Take a case in which the clock signal frequency is 500 MHz as an example. When using clock signals having a phase difference of 45°, it is necessary to propagate the clock signals for 23 mm while keeping 250 picoseconds (ps). 250 picoseconds are obtained by converting the phase difference of 45° to time. In this embodiment, however, 500 picoseconds obtained by converting a phase difference of 90° into time may be kept.

### Second Embodiment

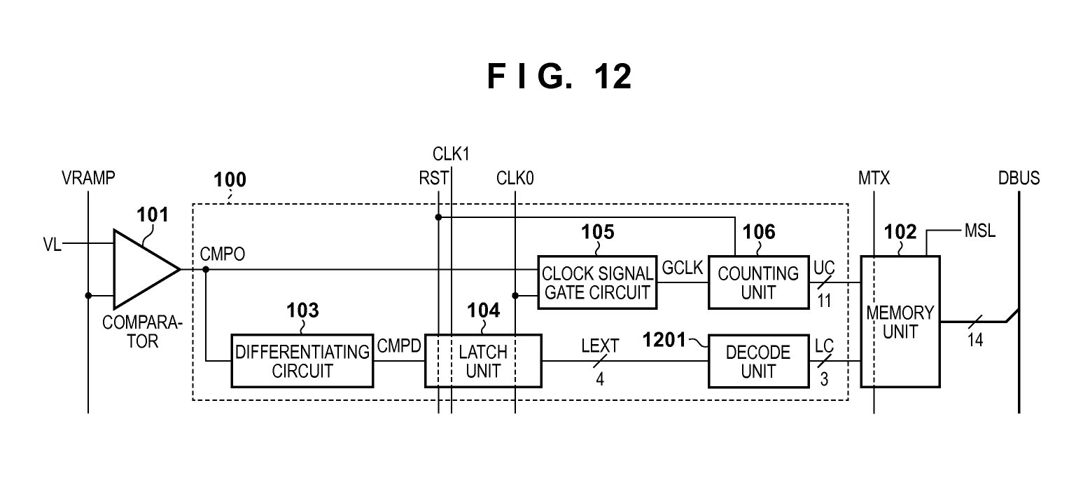

The second embodiment of the present invention will be described, mainly concerning differences from the first embodiment. FIG. 12 shows an example of the arrangement of an A/D converter according to the present invention. This embodiment is different from the first embodiment in that a decode unit 1201 is connected to the output of a latch unit 104. This embodiment is the same as the first embodiment until a lower extension code LEXT [3:0] is generated in the latch unit 104, and a description thereof will be omitted. The decode unit 1201 has a function of generating 3-bit lower count values LC [2:0] from 4-bit lower extension codes LEXT [3:0]. Decoding from a lower extension code to a lower count value LC is performed according to a decode table shown in FIG. 8. Since the number of bits of data input to a memory unit 102 can be reduced by this embodiment, 1-bit reduction in a memory amount can be achieved as compared to the first embodiment. A data bus DBUS is a digital code with which 11-bit upper count values UC [10:0] and 3-bit lower count values LC [2:0] are concatenated. This makes it unnecessary to decode a signal in a signal processing circuit which performs image processing, thus simplifying processing.

### Third Embodiment

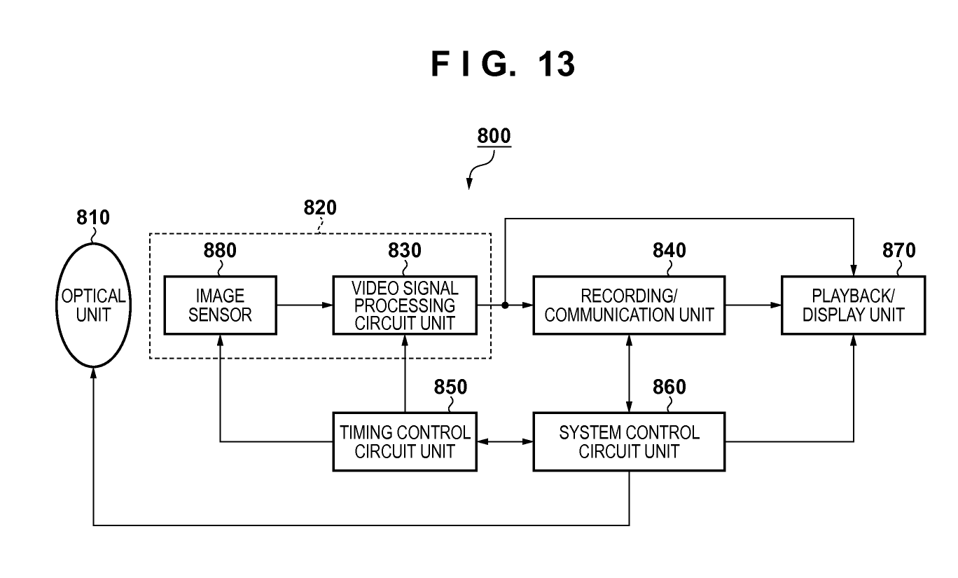

FIG. 13 is a diagram showing an example of the arrangement of an imaging system. An imaging system 800 includes, for example, an optical unit 810, an image sensor 880, a video signal processing circuit unit 830, a recording/communication unit 840, a timing control circuit unit 850, a system control circuit unit 860, and a playback/display unit 870. An image capturing apparatus 820 has the image sensor 880 and the video signal processing circuit unit 830. The solid-state image sensor described in the first embodiment is used as the image sensor 880.

The optical unit 810 serving as an optical system such as a lens forms an object image by forming light traveling from an object into an image in the pixel of the image sensor 880 in which a plurality of pixels are two-dimensionally arrayed. At a timing based on a signal from the timing control circuit unit 850, the image sensor 880 outputs a signal corresponding to the light formed into an image in the pixel unit. The video signal processing circuit unit 830 serving as a video signal processing unit receives the signal output from the image sensor 880, and performs signal processing on the signal, thereby outputting it as image data. The signal obtained by processing by the video signal processing circuit unit 830 is sent as the image data to the recording/communication unit 840. The recording/communication unit 840 sends, to the playback/display unit 870, a signal for forming an image, and causes the playback/display unit 870 to play back and display a moving image or a still image. Also, the recording/communication unit 840 communicates with the system control circuit unit 860 in response to a signal received from the video signal processing circuit unit 830. In addition, the recording/communication unit 840 performs an operation of recording, on a recording medium (not shown), a signal for forming an image.

The system control circuit unit 860 performs centralized control of the operation of the imaging system, and controls driving of the optical unit 810, the timing control circuit unit 850, the recording/communication unit 840, and the playback/display unit 870. The system control circuit unit 860 includes a storage device (not shown) serving as, for example, a recording medium, on which a program or the like necessary to control the operation of the imaging system is recorded. The system control circuit unit 860 supplies, into the imaging system, a signal for switching the driving mode in accordance with, for example, a user operation. Examples are a change of a row in which a signal is read out from the image sensor or a row to be reset, a change of the field angle along with electronic zooming, and a shift of the field angle along with electronic vibration isolation. The timing control circuit unit 850 controls the driving timings of the image sensor 880 and the video signal processing circuit unit 830 under the control of the system control circuit unit 860.

In each embodiment described above, the case in which the comparator receives the ramp signal which changes linearly with respect to time has been described. However, a signal level may change not only linearly but also stepwise. That is, the comparator may receive a reference signal whose signal level changes monotonically with respect to time.

Also, in each embodiment described above, the example in which the clock signal gate circuit 105 receives the clock signal CLK0, and the counting unit 106 receives the gated clock signal GCLK via the clock signal gate circuit 105 has been described. However, a clock signal CLK0 input to a latch unit 104 and a clock signal GCLK input to a counting unit 106 are in-phase clock signals.

According to the present invention, there is provided, in an A/D converter using clock signals having a different phase, a technique advantageous in achieving a resolution higher than a value corresponding to the phase difference.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-236262, filed Nov. 14, 2013, which is hereby incorporated by reference herein in its entirety.

What is claimed is:

1. An A/D converter comprising:
a comparator configured to compare an input voltage and a reference signal changing monotonically with respect to time, and output a comparison result signal indicating a comparison result;
a pulse signal generation circuit configured to generate a pulse signal in accordance with the comparison result signal;
a counting unit configured to receive a first clock signal, and to count the first clock signal from a start of changing a level of the reference signal to when a level of the comparison result signal is changed; and
a latch unit configured to latch the pulse signal at a timing which is defined by a plurality of clock signals including a second clock signal in phase with the first clock signal and a third clock signal having a different phase from that of the second clock signal.

2. The converter according to claim 1, wherein digital data having an output signal from the counting unit as upper digit data and an output signal from the latch unit as lower digit data is output.

3. The converter according to claim 1, wherein a pulse width of the pulse signal is larger than a minimum value of a phase difference between the second clock signal and a plurality of clock signals each having a different phase from that of the second clock signal, and smaller than a value which is three times of the minimum value of the phase difference.

4. The converter according to claim 1, wherein the first clock signal input to the counting unit is inhibited in accordance with the comparison result signal.

5. The converter according to claim 1, wherein a minimum value of a phase difference between the second clock signal and a plurality of clock signals each having a different phase from that of the second clock signal is π/2.

6. The converter according to claim 5, wherein a pulse width of the pulse signal is larger than π/2 of the phase difference between the clock signals, and smaller than π.

7. The converter according to claim 5, wherein the plurality of clock signals having the different phases include four clock signals, and a pulse width of the pulse signal is 3π/4 of a clock signal cycle.

8. The converter according to claim 1, further comprising a memory unit configured to hold an output signal from the counting unit and an output signal from the latch unit.

9. The converter according to claim 1, further comprising a decode unit configured to decode an output signal from the latch unit.

10. The converter according to claim 9, further comprising a memory unit configured to hold an output signal from the decode unit.

11. A solid-state image sensor comprising:
a plurality of pixels arranged in a row direction and a column direction, and an A/D converter defined in claim 1 and configured to convert, by column of the plurality of pixels, a pixel signal into digital data.

12. An imaging system comprising:
a solid-state image sensor defined in claim 11, an optical unit configured to form light into an image in the solid-state image sensor, and a signal processing circuit configured to process an output signal from the solid-state image sensor.
